(19) United States
(12) Patent Application Publication
(10) Pub. No.: US 2015/0156913 A1
(43) Pub. Date: Jun. 4, 2015

(54) Forced Directional Heat Flow Structures and Methods

(71) Applicant: JONATHAN RYAN WILKERSON, Morrisville, NC (US)

(72) Inventor: JONATHAN RYAN WILKERSON, Morrisville, NC (US)

(21) Appl. No.: 14/280,543

(22) Filed: May 16, 2014

Related U.S. Application Data
(60) Provisional application No. 61/823,937, filed on May 16, 2013.

(51) Int. Cl. H05K 7/20

(52) U.S. Cl. CPC H05K 7/2039

(57) ABSTRACT

This disclosure discusses methods and processes to force directional heat flow from a heat source such as a transistor, group of transistors, integrated circuit, or other heat source to a desirable location while preventing heat flow in other directions. Such directional heat flow can occur through the strategic placement of thermal insulator and thermal conductor layers. Both thermal insulator and thermal conductor should be alternating and must have a significant difference in thermal conductivity. Loss of heat from the directional heat guide is controlled by either alternating layers of thermal conductor and insulator, or by increasing the disparity in thermal conductivities between the thermal conductor and insulator, or both.

### CROSS-REFERENCE TO RELATED APPLICATIONS

This patent claims priority from the provisional patent application 61/823,937.

### STATEMENT REGARDING FEDERALLY SPONSORED RESEARCH OR DEVELOPMENT

N/A

### REFERENCE TO SEQUENTIAL LISTING, A TABLE, OR A COMPUTER PROGRAM LISTING APPENDIX SUBMITTED ON A COMPACT DISC

N/A

### FIGURES AND DRAWINGS

### BACKGROUND OF THE INVENTION

1. Field of the Invention

This invention is in the field of transistors. More specifically, this invention is in the field of removing heat from transistors without requiring additional external cooling devices.

2. Description of the Related Art

Transistors are utilized in electrical circuits of all types in order to process or alter information and signals in a beneficial manner. Electrical system performance, or even functionality, is often limited by heat dissipation in individual transistors or the net heat output of a group of transistors. Regardless of low power design methodologies and power management techniques, fundamentally there will always be some amount of electrical power dissipated, which is turned into heat. There is a fundamental need for technologies to remove heat from a transistor, or other electrical heat source, without impacting its electrical performance or spreading the heat to other circuits in order to both increase performance and reduce cooling costs and complexity.

Further driving the need for integrated circuit level cooling solutions is the move to three-dimensional and stacked integrated circuits. Stacked integrated circuits lack a readily accessible thermal dissipation channel, especially in thinned die, causing significantly higher temperature rises in circuits that can inhibit performance severely. In addition, three-dimensional multi-gate transistors such as FinFETs continue to increase the power density, and thus heat generation, of integrated circuits. Limited options currently exist to address these cooling issues including thermal vias to increase the total thermal conductivity of each integrated circuit substrate, active thermoelectric cooling, and microfluidic cooling channels, among others. There is a need for a device level solution that can control thermal gradients and temperature rise in stacked and three-dimensional integrated circuit structures.

Packaged integrated circuits, three-dimensional or two-dimensional, must be cooled at the motherboard level and at the housing facility level as well. At these levels, integrated circuits act as heaters in the facilities in which they are housed, which have to be cooled by HVAC or liquid cooling systems, often requiring significant energy to operate inside a facility. The heat is spread as quickly as possible in virtually all cooling solutions to the local air in order to guarantee electrical performance, resulting in large electronics operating costs. There is a need to reduce these cooling costs as well.

### SUMMARY OF THE INVENTION

Heat is by nature diffusive and spreads from its source in a manner that will most efficiently spread the heat. The invention described herein, a directional heat guide and directional heat guide coupled transistor, entraps and guides heat in a preferred direction while preventing it from spreading in other directions.

The directional heat guide in its simplest form is created by encasing a thermal conductor in a thermal insulator, with the two materials having a significant difference in thermal conductivity. The loss of heat from the directional heat guide is controlled by alternating layers of thermal conductor and insulator, or by increasing the disparity in thermal conductivities between the thermal conductor and insulator, or both.

A directional heat guide coupled transistor is a transistor with drain, source, or channel directly coupled to a directional heat guide at the device level. The heat generated by the coupled transistor is isolated from other transistors and is directed to preferable heat transfer or dissipation locations, as opposed to diffusing through the die.

### BRIEF DESCRIPTION OF THE FIGURES AND DRAWINGS

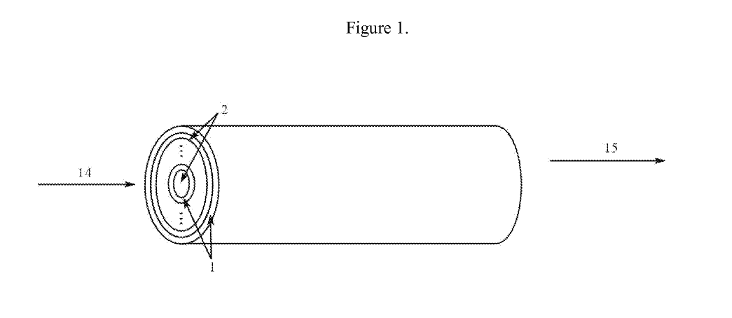

FIG. 1 is an example of a general case directional heat guide. Necessary coupling for heat to be trapped in heat guide is not shown within this figure. Thermal insulators (1) encase thermal conductors (2) within the heat guide to better transfer the heat from the source. Heat from the heat source (14) leads into the directional heat guide before being directed to the next level of heat transfer (15).

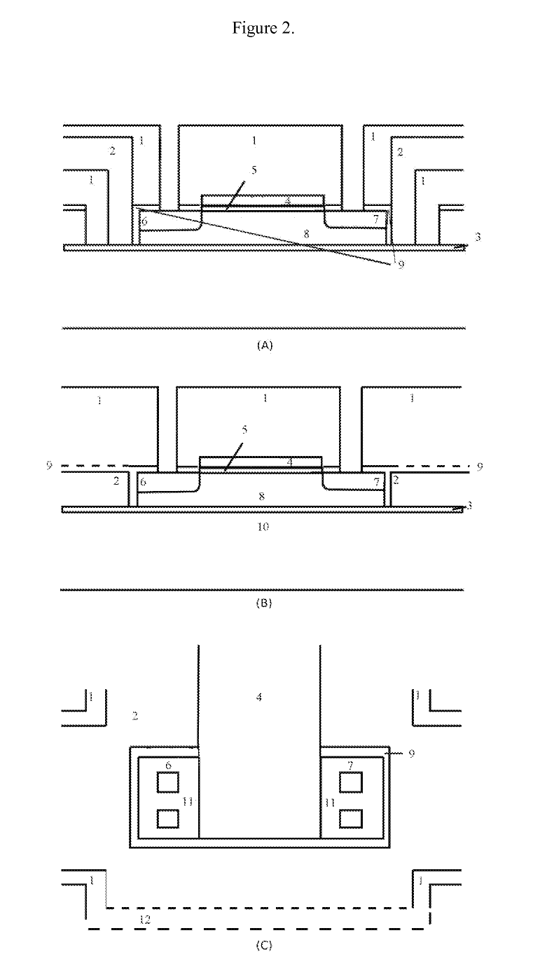

FIG. 2 displays several directional heat guide transistor views. FIG. 2(a) exhibits a cross section of the heat guide going through a layer above the transistor. (3) designates thermal electrical insulators. (4) represents the gate. (5) represents the gate insulator. (6) represents the source. (7) represents the drain. (8) represents the doped semiconductor. (9) represents coupling barriers. FIG. 2(b) exhibits the cross section of a heat guide formed entirely in isolation trenches. (10) represents the bulk semiconductor. FIG. 2(c) exhibits the top view of the transistor, heat guides, and termination structure for non-routed heat guides. (11) represents electrical contacts. (12) represents optional terminations.

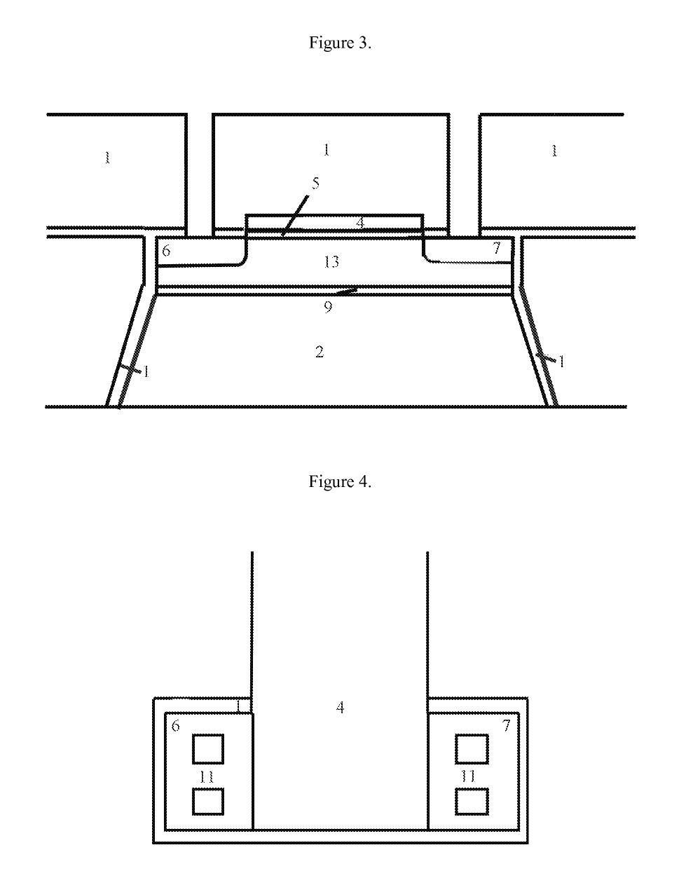

FIG. 3 displays the cross section of a directionally heat guided transistor with heat conduction port contacting the bottom of the transistor only and porting heat to the bottom of the substrate.

FIG. 4 displays the top view of a transistor showing thermal insulation surrounding the transistor.

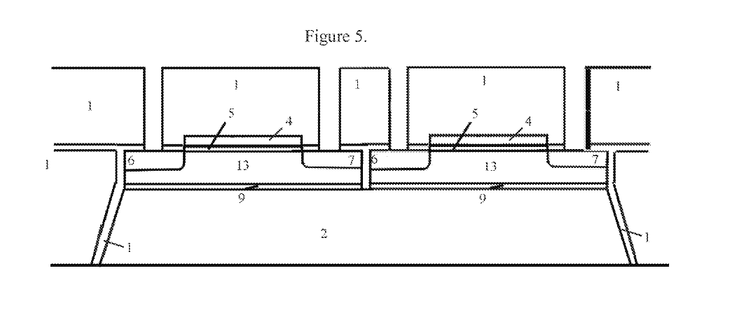

FIG. 5 displays a group of transistors coupled to a thermal guide for directional heat flow control.

### DETAILED DESCRIPTION OF THE INVENTION

A directional heat guide is a structure that confines heat and guides it in a single, preferred direction away from a heat source. The directional heat guide structure is formed by alternating layers of a material with thermal conductivity k₁, k₃, k₅, k₍ₙ₋₁₎ with layers of a material with thermal conductivity k₂, k₄, kₙ where material i always has lower thermal conductivity than material₍ᵢ₋₁₎ and material₍ᵢ₋₁₎ has higher thermal conductivity than material₍ᵢ₋₂₎. Referring to FIG. 1, a high thermal conductivity material, thermal conductor one, is encased in a lower thermal conductivity material, thermal insulator one. Thermal insulator one is encased in thermal conductor two, which has higher thermal conductivity than thermal insulator one but is not necessarily equal to the thermal conductivity of thermal conductor one. Thermal conductor two is encased in thermal insulator two, which has lower thermal conductivity than thermal conductor two but not necessarily equal to thermal insulator one. The structure can be continued for any desired number of layers according to heat leakage suppression requirements, but can be as few as one layer of thermal conductor and thermal insulator. The structure is always terminated in a thermal insulator. At least thermal conductor one, but up to thermal conductor N, must be connected to a heat source either directly or through a coupling barrier material that can also provide electrical isolation. Said coupling barrier material can be an oxide, nitride, oxynitride, ceramic, or other material. The thermal insulator of the outermost thermal conductor that is in contact with the heat source must be at least partially surrounding the heat source to cause efficient coupling into the directional heat guide. The directional heat guide is terminated on the other end by either another directional heat guide or by a heat removal method such as a heat sink, thermoelectric cooler, fluidic cooling, or other applicable method.

A directionally heat guided transistor is a transistor that has thermal isolation at least partially surrounding it with at least one thermal guide connected to its source, drain, or conduction channel through a coupling barrier. The coupled thermal guide directs the heat generated by the transistor to the surface, top or bottom, of the chip for removal via another directional heat guide if routing through another chip or to a heat removal mechanism.

Referring to FIG. 2, the bottom of the source, drain, and bulk including the conduction channel are at least partially bordered by a thermal insulator, preferably an oxide, but any material with low thermal conductivity, preferably k<=5. The sides or the source, drain, and bulk including the conduction channel are contacted by a coupling barrier which is an electrical insulator, preferably having thermal conductivity of 10 or greater, which could be a nitride, oxynitride, or other suitable material. The coupling barrier is contacted directly by a high thermal conductivity material, the thermal conductor, with k at least >50, but preferably 125-400 or more, which could be a metal, semiconductor, or ceramic. The high thermal conductor material is bordered on the bottom by the thermal insulator contacting the bottom of the source, drain, and bulk including the conduction channel. The thermal conductor is also bordered on the sides and top by a thermal insulator (k<=5). The directional heat guide can be routed in any direction, or in many directions, away from the transistor. Any area of the thermal conductor that is not to be routed is terminated in a thermal insulator (k<=5), shown in FIG. 2c. The heat travels through said directional heat guide to either a heat reservoir, which is also completely encased in a thermal insulator, or to the top of the chip through a set of vias that are not connected to any other laterally routed metal other than the heat guide itself and are completely surrounded by a thermal insulator (k<=5), or to the bottom of the chip through a through silicon via that is completely encased in thermal insulator (k<=5). The heat guide can be formed at the same level as the source, drain, and conduction channel, as shown in FIG. 2b, or can be transferred to higher layers as in FIG. 2a. Please note that the figures and drawings are representative of embodiments of the invention and are not to scale.

Additionally, for multi-gate three dimensional transistors with very small conduction channels such as FinFETs, directional heat guides are formed in the same structure but only contact the drain and source of the transistor.

For multiple die systems where the die are mounted on top of each other, the directional heat guides of one chip may be directly coupled to the second chip to maintain directional thermal transport and isolation between chips until a heat removal point is reached. In this case, the thermal conductor of each directional thermal guide is recessed beneath a thermal insulator and then connected through solder or a thermal coupling compound to each other. The thermal coupling compound or solder is applied in such a way as to not contact any other surface that is not thermally insulated.

A second type of directionally heat guided transistor structure is shown in cross section in FIG. 3 and top view in FIG. 4, where the bottom of the source, drain, and bulk including the conduction channel are completely bordered by a coupling barrier which is an electrical insulator, preferably having thermal conductivity of 10 or greater, which could be a nitride, oxynitride, or other suitable material. The sides or the source, drain, and bulk including the conduction channel are contacted by a thermal insulator, preferably an oxide, but any material with low thermal conductivity, preferably k<=5, which further extends through the substrate to the bottom of the chip. The coupling barrier and thermal insulator is contacted directly by a high thermal conductivity material, the thermal conductor, with k at least >50, but preferably 125-400 or more, which could be a metal, semiconductor, or ceramic. The heat travels through said directional heat guide to the bottom of the chip where it contacts a heat removal mechanism or a second directional heat guide.

Additionally, the heat guide can encase a number of transistors where the outermost transistor define the thermal insulator of the heat guide, as shown in FIG. 5.

### EMBODIMENTS OF THE INVENTION

According to one embodiment of the present disclosure, a heat guiding structure includes a thermally conductive material encased by a layer of thermally insulating material for the length of the intended directional heat conduction path. The heat guiding structure can further include an additional encasement of thermal conductor in direct contact with the first layer of thermally insulating material and an additional encasement of thermal insulator in direct contact with the second layer of thermally conducting material. Additional encasements in the same sequence can be added to further increase heat guiding efficiency if necessary. Heat guiding efficiency is determined by the number of layers and the ratio of thermal conductivities of the layers. Temperature rise in the heat guide is mostly determined by the area and thermal conductivity of the primary thermal conductor.

In a second embodiment of the present disclosure, a structure of a transistor with heat guiding structures for source, drain, and bulk regions including the conduction channel includes a directional heat guide composed of at least one layer or more of thermal conductor encased in a thermal insulator. The heat guide is connected to a transistor source, drain, or bulk region, with connection to source or drain region through a coupling material that provides electrical isolation, and then connecting to the thermal conductor of the directional heat guide. The encasing thermal insulator should be at least partially insulating the drain or source region. The directional heat guide should extend to a desired heat removal location, preferably, but not limited to, either a heat reservoir or vertical directional heat guide, and finally coupled to a second directional heat guide in another die or a heat removal point.

In a third embodiment of the present disclosure, a structure of a transistor with a vertical heat guiding structure for source, drain, and channel regions includes: a transistor surrounded along its perimeter by thermal insulator at least equal to the depth of the source and drain regions; an electrical insulator that is thermally conductive to a degree contacting the bottom of the transistor or substrate directly under the transistor within the thermally insulated region; and a directional heat guide which connects vertically through to the electrically insulating partially thermally conductive region.

In a fourth embodiment of the present disclosure, a structure of a group of transistors with vertical heat guiding structure regions includes: a group of transistors surrounded along their perimeter by thermal insulator at least equal to the depth of the source and drain regions; an electrical insulator that is thermally conductive to a degree contacting the bottom of the transistors or substrate directly under the transistors within the thermally insulated region; and a directional thermal guide which connects vertically through to the electrically insulating partially thermally conductive region.

1. A directional heat guiding structure comprising: a length of inner thermally conductive material; a thermally insulating material or group of materials wrapped around the inner thermal conductive material for the length of the thermally conductive material; the inner thermally conductive material in contact with a heat source either directly or through a thin coupling barrier material that provides electrical insulation; at least partial thermal insulation of the heat source, or heat flowing from the heat source, by the thermally insulating sheath.

2. The heat guiding structure of claim 1, further comprising an additional layer of thermal conductor fully wrapping the first thermal insulator and first thermal conductor for their entire length, and an additional layer of thermal insulator fully wrapping the second thermal conductor, first thermal insulator, and first thermal conductor for their entire length.

3. The heat guiding structure of claim 2, further comprising additional layers of thermal conductor and thermal insulator fully wrapping all prior layers of thermal conductor and thermal insulator for their entire length.

4. The heat guiding structure of claim 1, further comprising ends where at least the innermost thermal insulator at least partially encases a heat reservoir or thermal conductor from a second directional heat guide and the innermost thermal conductor is in direct mechanical contact, epoxied, or connected through thermal paste directly to the heat reservoir or thermal conductor of the second directional heat guide.

5. A coupled transistor-directional heat guiding structure comprising: a transistor having a current conduction channel with channel current controlled by an applied voltage or current; a drain region and source region to supply said channel current; a thin coupling barrier that provides electrical insulation at least partially covering the drain and source regions, but preferentially covering all sides of the transistor except the top and bottom of the transistor; a thermal conductor in contact with the thin coupling barrier and extending a length away from the source, drain, or channel regions; a thermal insulator encasing the thermal conductor down its length; a thermal insulator that terminates any thermal conductor in any direction where no directional heat guide or electrical signal is routed; a heat reservoir(s) or second directional heat guide(s) that the transistor coupled heat guide(s) transfer heat to.

6. The coupled transistor-directional heat guide structure of claim 5, further comprising a vertical via stack routed from a heat reservoir on the heat reservoir or directional heat guide layer directly to a heat reservoir on a die surface.

7. The coupled transistor-directional heat guide structure of claim 5, further comprising a through silicon via in contact with a heat reservoir or directional heat guide on the heat guide layer connecting directly to a heat reservoir on a die surface.

8. A coupled transistor-directional heat guiding structure comprising: a transistor having a current conduction channel with channel current controlled by an applied voltage or current; a drain region and source region to supply said channel current; a thin coupling barrier that provides electrical insulation at least partially contacting the bottom of the drain, source, and channel regions, but preferentially covering the entire bottom of the transistor; a thermal insulator that surrounds at least every side of the transistor except for the top and bottom of the transistor, although the top of the transistor may also be surrounded by the thermal insulator; a thermal insulator that contacts the thermal insulator surrounding the transistor and extends through the substrate, at least partially, and bounds the coupling barrier; a thermal conductor in contact with the thin coupling barrier along its surface and further in contact with the thermal insulator extending at least partially down the substrate, where the thermal insulator encases the thermal conductor down its length through the substrate; a heat reservoir on the bottom of the substrate.

9. A couple group of transistors-directional heat guiding structure comprising: a group of transistors generating heat; a thin coupling barrier that provides electrical insulation at least partially contacting the bottom of the drain, source, and channel regions of the group of transistors, but preferentially covering the entire bottom of the group of transistors; a thermal insulator that surrounds at least every side of the group of transistors except for the top and bottom of the transistors, although the top of the transistor may also be surrounded by the thermal insulator; a thermal insulator that contacts the thermal insulator surrounding the group of transistors and extends through the substrate, at least partially, and bounds the coupling barrier; a thermal conductor in contact with the thin coupling barrier along its surface and further in contact with the thermal insulator extending at least partially down through the substrate, where the thermal insulator encases the thermal conductor down its length through the substrate; a heat reservoir or second directional heat guide on the bottom of the substrate which the thermal conductor transfers the heat.

10. A multi-die directional heat guide structure comprising: a coupled transistor-directional heat guide or group of coupled transistors-directional heat guide structure where the directional heat guide is routed to the surface of the die; a second directional heat guide in a second die further comprising ends where at least the innermost thermal insulator at least partially encases the thermal conductor from the first directional heat guide and the innermost thermal conductor of the second directional heat guide is in direct mechanical contact, epoxied, or connected through thermal paste directly to the thermal conductor of the first directional heat guide.
